(19) United States
(12) Patent Application Publication
(10) Pub. No.: US 2018/0181465 A1
(43) Pub. Date: Jun. 28, 2018

(54) SYNCHRONIZED READ AND WRITE FLAGS FOR ERROR-FREE MEMORY MODULE INTERFACE

(71) Applicant: Western Digital Technologies, Inc., Irvine, CA (US)

(72) Inventors: Won Ho CHOI, San Jose, CA (US); Jay KUMAR, Saratoga, CA (US); Kiran Kumar GUNNAM, Milpitas, CA (US); Dejan VUCINIC, San Jose, CA (US); Zvonimir Z. BANDIC, San Jose, CA (US)

(73) Assignee: Western Digital Technologies, Inc.

(21) Appl. No.: 15/388,660

(22) Filed: Dec. 22, 2016

(51) Int. Cl. G06F 11/10; G06F 11/07; G11C 29/52

(52) U.S. Cl. CPC G06F 11/1072; G11C 29/52; G06F 11/0787; G06F 11/076

(57) ABSTRACT

The present disclosure generally relate to a device and method for ensuring error-free memory. Synchronized read and write flags generated by a memory portion are used to make a memory controller of a host portion free from error correction, read/write disturbance, wear leveling and any systematic read/write issues that may occur.

### BACKGROUND OF THE DISCLOSURE

### Field of the Disclosure

Embodiments of the present disclosure generally relate to a device and method for ensuring error-free memory.

### Description of the Related Art

Devices such as computers include host portions and memory portions. The memory portion interfaces with host portion of the device. In typical operation, the host portion requests data to be read from the memory portion or the host portion requests data to be written to the memory portion.

When following the instruction from the host portion, the memory portion may experience errors due to device malfunctions, data not yet ready to be read, device overheating or systematic issues within the memory module. These errors can lead to bad data or no data communicated to the host portion in the case of read operations. In the case of write operations, the errors can lead to incorrectly written data. In some cases, the errors could lead to data not being written to the memory portion at all.

The memory portion does not provide any read or write error information back to the host portion. Thus, when errors occur, the host portion has a difficult time dealing with the errors.

Therefore, there is a need in the art for a communication of read and/or write errors from the memory portion to the host portion.

### SUMMARY OF THE DISCLOSURE

The present disclosure generally relate to a device and method for ensuring error-free memory. Synchronized read and write flags generated by a memory portion are used to make a memory controller of a host portion free from error correction, read/write disturbance, wear leveling and any systematic read/write issues that may occur.

In one embodiment, a device comprises a host portion; and a memory portion coupled to the host portion. The memory portion includes a media controller coupled to the host portion; and one or more media coupled to the media controller. The media controller and/or memory elements include a flag generator; a syndrome checker coupled to the flag generator; and an error correction code (ECC) block coupled to the syndrome checker.

In another embodiment, a method of reading data from a device comprises sending a read request from a host portion to a memory portion of the device; performing a one-time read from data devices in the memory portion of the device; checking for errors; detecting errors in the data read from the data devices; raising a read flag from the memory portion to indicate that the read data is not ready; requesting host device to issue a re-read request after a predetermined delay; performing error code correction from the memory device; checking for errors; and transferring the read data to the host portion.

In another embodiment, a method of writing data to a device comprises sending a write request from a host portion to a memory portion of the device; checking for errors in the memory portion; detecting systematic write issues with the memory portion; raising a write flag from the memory portion to indicate that the write cannot be performed; re-checking for errors; and transferring the write data to the memory portion.

In another embodiment, a device comprises a host portion; and a memory portion coupled to the host portion. The memory portion includes: means for performing a one-time read from data devices in the memory portion of the device; means for checking for errors; means for detecting errors in the data read from the data devices; means for raising a read flag from the memory portion to indicate that the read data is not ready; means for requesting host device to issue a re-read request after a predetermined delay; means for performing error code correction from the memory device; means for checking for errors; and means for transferring the read data to the host portion.

In another embodiment, a device comprises a host portion; and a memory portion coupled to the host portion. The memory portion includes: means for sending a write request from a host portion to a memory portion of the device; means for checking for errors in the memory portion; means for detecting systematic write issues with the memory portion; means for raising a write flag from the memory portion to indicate that the write cannot be performed; means for re-checking for errors; and means for transferring the write data to the memory portion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a simplified schematic illustration of a device according to one embodiment.

FIG. 1B is a simplified schematic illustration of the memory portion.

FIG. 2 is a flow chart illustrating a read process according to one embodiment.

FIG. 3 is a flow chart illustrating a write process according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relate to a device and method for ensuring error-free memory. Synchronized read and write flags generated by a memory portion are used to make a memory controller of a host portion free from error correction, read/write disturbance, wear leveling and any systematic read/write issues that may occur.

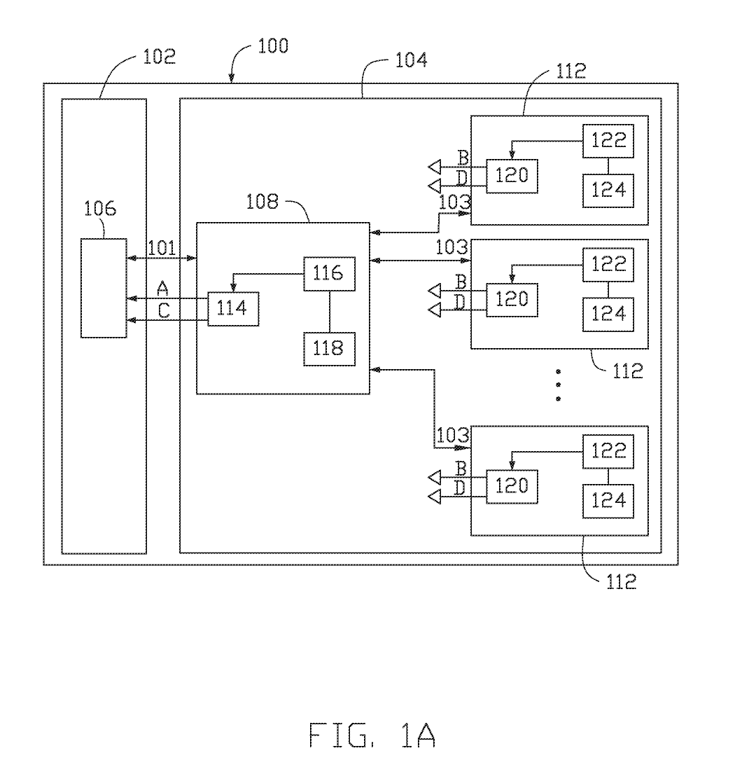

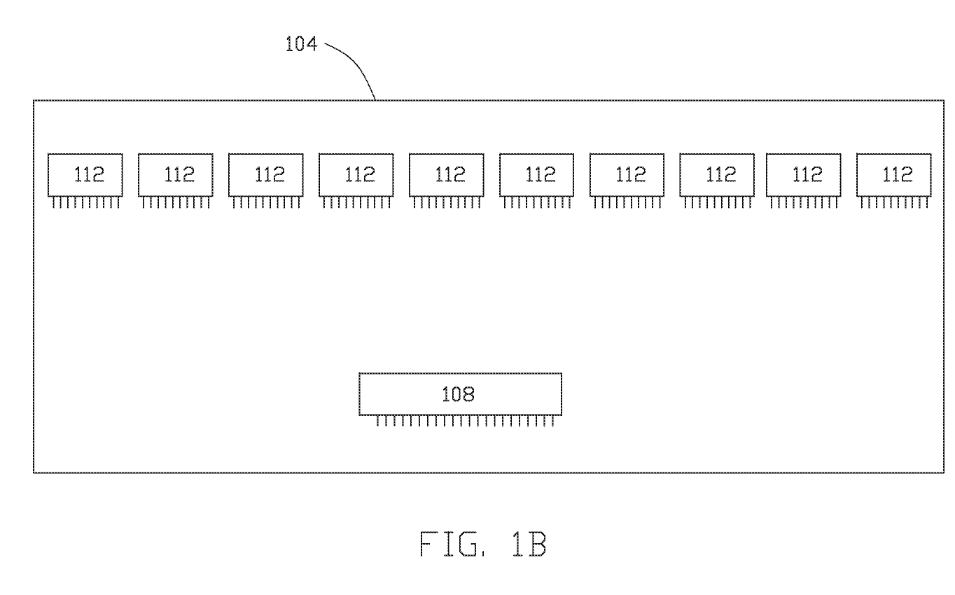

FIG. 1A is a simplified schematic illustration of a device 100 according to one embodiment. The device 100 includes a host portion 102 coupled to a memory portion 104. Data are transferred between the host portion 102 and the memory portion 104 through multiple data lines 101. The host portion 102 includes a memory controller 106. In one embodiment, the host portion 102 is a central processing unit (CPU).

FIG. 1B is a simplified schematic illustration of the memory portion 104. In one embodiment, the memory portion is NVDIMM. The NVDIMM may be NVDIMM-P. The memory portion 104 includes a media controller 108 and a plurality of memory elements 112 for storing data. In one embodiment, the memory elements 112 are non-volatile memories (NVMs). In another embodiment, the memory elements 112 are dynamic random access memories (DRAMs). In still another embodiment, the memory elements 112 are a combination of NVMs and DRAM. Data are transferred between the media controller 108 and each memory element 112 through multiple data lines 103. Separate multiple data lines 103 are present between each memory element 112 and the media controller.

The media controller 108 includes a flag generator 114, a syndrome checker 116 and an ECC block 118. The ECC block 118 is coupled to the syndrome checker 116, and the syndrome checker 116 is coupled to the flag generator 114. The media controller 108 is coupled to the memory controller 106 of the host portion 102. More specifically, the flag generator 114 of the media controller 108 is coupled to the memory controller 106 of the host portion 102.

The memory elements 112 may each include a flag generator 120, a syndrome checker 122 and an ECC block 124. The ECC block 124 is coupled to the syndrome checker 122, and the syndrome checker 122 is coupled to the flag generator 120.

The flag generators 114, 120 generate read flags and write flags when necessary based upon errors detected by the syndrome checkers 116, 122. It is to be understood that while FIG. 1 shows both the media controller 108 and each memory element 112 to have flag generators, syndrome checkers and ECC blocks, it is envisioned that either the media controller 108, one or more memory elements 112, or a combination of both (as shown in FIG. 1A), have the flag generators, syndrome checkers and ECC blocks. In any event, any flag generators that are present are coupled to the memory controller 106 of the host portion 102. Most specifically, the read flag is sent to the memory controller 106 as shown by arrow “A” from the flag generator 114 or through arrows “B” from flag generators 120. Similarly, write flags are sent to the memory controller 106 as shown by arrow “C” from the flag generator 114 of through arrows “D” from flag generators 120.

For read operations, the read flag is provided by each individual memory element 112 or the media controller 108. In one embodiment, each memory element 112 will handle the error corrections via the respective ECC 124 and the syndrome checker 122 which will tell the flag generator 120 to generate a flag. The read flag may be raised when the reads cannot be accepted due to any systematic read issues on the memory element 112. The read flag tells the memory controller 106 that the read is not ready and requests the memory controller 106 to issue a re-read instruction with a pre-fixed parameter (i.e., after a predetermined period of time).

For write operations, the write flag can be provided in a similar manner. The write flag tells the memory controller 106 that the write cannot occur due to write issues such as device overheating, wear leveling or any systematic write issues on the memory element 112.

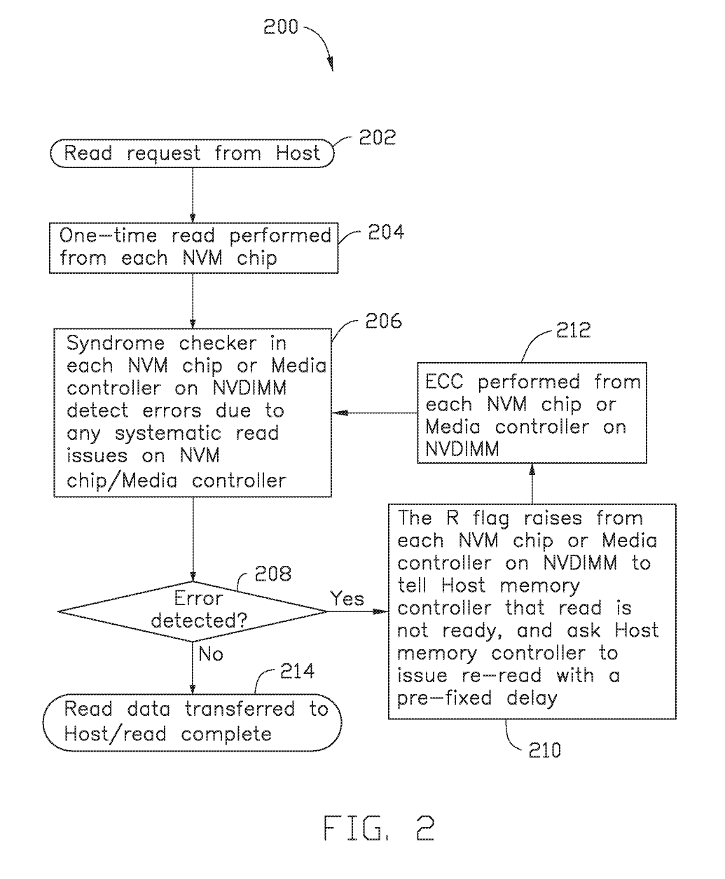

FIG. 2 is a flow chart 200 illustrating a read process according to one embodiment. The process beings when the host portion 102 sends a read request to the memory portion 104 in block 202. A one-time read operation is performed from each memory element 112 in block 204. In the case of FIG. 2, the memory elements 112 are NVMs, but it is to be understood that method is equally applicable to memory elements 112 such as DRAM, NVM, and combinations thereof. The syndrome checker that is in each NVM chip or in the media controller 108 on the NVDIMM detects errors due to any systematic read issues on the NVM chip or the media controller 108 in block 206. If an effort is detected in block 208, then a read flag raises from each NVM chip or the media controller 108 on the NVDIMM in block 210. The host portion 102 memory controller 106 is informed that the memory portion 104 is not ready. Additionally, the host portion 102 is asked to issue a re-read command with a pre-fixed delay (i.e., issue the re-read command after a predetermined delay). Thereafter, error correction is performed for each affected NVM chip or the media controller 108 on the NVDIMM in block 212 using an ECC. After the error correct is performed, the syndrome checker again checks for errors due to any systematic read issues on the NVM chip or the media controller 108 in block 206. If no errors are detected in block 208, then the read data is transferred to the host portion 102 and the read operation is complete in block 214.

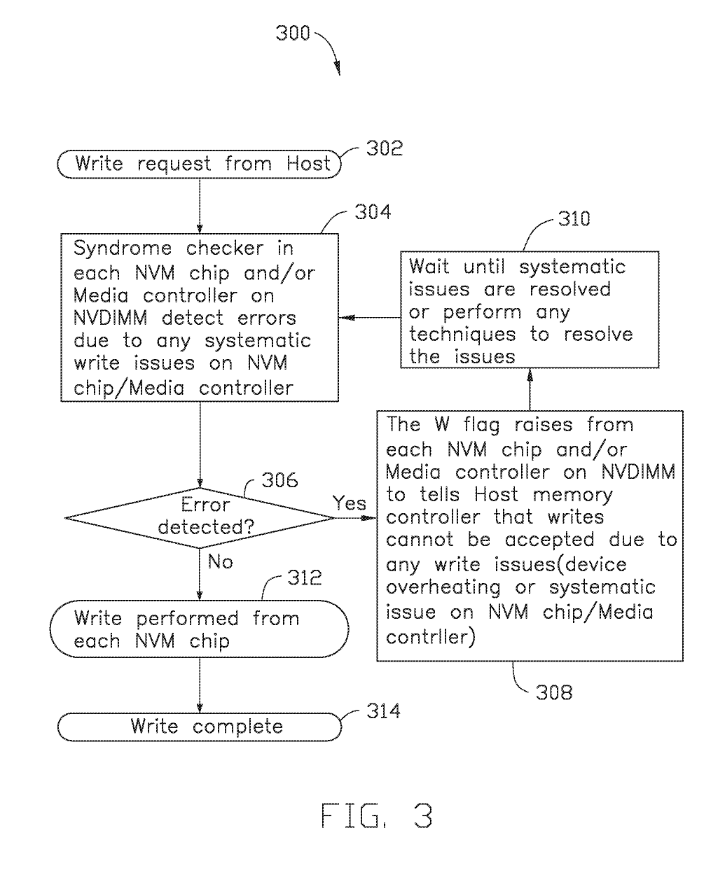

FIG. 3 is a flow chart 300 illustrating a write process according to one embodiment. The process begins in block 302 when the host portion 102 issues a write request to the memory portion 104. The syndrome checker in each NVM chip and/or the media controller 108 on the NVDIMM checks for errors due to any systematic write issues on any NVM chip or the media controller 108 in block 304. In the case of FIG. 3, the memory elements 112 are NVMs, but it is to be understood that method is equally applicable to memory elements 112 such as DRAM, NVM, and combinations thereof. If an error is detected in block 306, a write flag is raised from each affected NVM chip or the media controller 108 on the NVDIMM. The host portion 102 memory controller 106 is informed that a write operation cannot occur due to write issues such as device overheating, systematic issues on the NVM or media controller 108, or wear leveling in block 308. The host portion 102 then waits in block 410 until the write issues have been resolved. Alternatively, the host portion 102 waits until the media controller 108 performs any techniques necessary to resolve the issues. After the waiting is over, the syndrome checker rechecks for errors due to any systematic write issues on any NVM chip or the media controller 108 in block 304. If there are no errors in block 306, then the write operation is performed for each NVM chip in block 312 necessary to have data written thereto. Finally, the write operation completes in block 314.

By communicating between a memory portion and a host portion of a device, write operations and read operations may be performed more efficiently. The communication allows the memory portion to inform the host portion that data may not yet be read from the memory portion memory elements due to the data not being ready to be read or problems with the memory element. The host portion then waits a predetermined period of time for the problem to be corrected or for the data to be ready for reading, and then the read operation proceeds. Similarly, in a write operation, the memory portion is able to inform the host portion that the data may not be written and instructs the host portion to wait for the problem to be corrected or for the data location in the memory element to be available for writing. Once the problem has been corrected or the data location is available, the write operation proceeds. Thus, the communication from the memory portion to the host portion, by way of read flags or write flags, synchronizes the host portion and memory portion and makes the device free from error correction, read/write disturbances, weal leveling and any systematic read/write issues.

While the foregoing is directed to embodiments of the present disclosure, other and further embodiments of the disclosure may be devised without departing from the basic scope thereof, and the scope thereof is determined by the claims that follow.

1. A device, comprising:
a host portion; and
a memory portion coupled to the host portion, wherein the memory portion includes:
a media controller coupled to the host portion; and
one or more dynamic random access memory (DRAM) or non-volatile memory (NVM) chips coupled to the media controller, wherein at least one of the NVM or DRAM includes:
an error flag generator;
a syndrome checker coupled to the flag generator; and
an error correction code (ECC) block coupled to the syndrome checker.

2. The device of claim 1, wherein the memory portion includes the DRAM, and wherein the DRAM includes the flag generator, the syndrome checker and the ECC block.

3. The device of claim 1, wherein the memory portion includes the NVM, and wherein the NVM includes the flag generator, the syndrome checker and the ECC block.

4. The device of claim 1, wherein the media controller includes the flag generator, the syndrome checker and the ECC block.

5. The device of claim 1, wherein the NVM and the media controller each include a flag generator, a syndrome checker and an ECC block.

6. The device of claim 1, wherein the host portion includes a memory controller.

7. The device of claim 6, wherein the memory controller is coupled to the media controller.

8. The device of claim 7, wherein the host portion is a CPU.

9. The device of claim 1, wherein the memory portion is a NVDIMM.

10. The device of claim 9, wherein the NVDIMM is NVDIMM-P.

11. The device of claim 1, wherein:
the host portion is a CPU and comprises a memory controller;
the media controller includes the flag generator, the syndrome checker, and the ECC block;
the memory controller is coupled to the flag generator;
the memory portion includes a plurality of NVM chips; and
the memory portion is NVDIMM-P.

12. A method of reading data from a device, comprising:
sending a read request from a host portion to a memory portion of the device;
performing a one-time read from the memory portion of the data device in the memory portion of the device;
checking for errors within the memory portion of the data device;
detecting errors in the data read from the data devices;
raising a read flag from the memory portion to indicate that the read data is not ready;
requesting host device to issue a re-read request after a predetermined delay;
performing error code correction from the memory device;
checking for errors; and
transferring the read data to the host portion.

13. The method of claim 12, wherein the data devices are NVMs.

14. The method of claim 12, wherein the memory portion is NVDIMM-P.

15. The method of claim 12, wherein the read flag is raised by a media controller.

16. A method of writing data to a device, comprising:
sending a write request from a host portion to a memory portion of the device;
checking for errors with an ECC block located within the memory portion;
detecting systematic write issues with the memory portion;
raising a write flag from the memory portion to indicate that the write cannot be performed;
re-checking for errors; and
transferring the write data to the memory portion.

17. The method of claim 16, wherein the memory portion includes NVMs.

18. The method of claim 17, wherein the NVMs raise the write flag.

19. The method of claim 16, wherein the memory portion is NVDIMM-P.

20. The method of claim 16, wherein the write flag is raised by a media controller.

21. A device, comprising:
a host portion; and
a memory portion coupled to the host portion, the memory portion including:
means for performing a one-time read from data devices in the memory portion of the device;
means for checking for errors located within the memory portion;
means for detecting errors in the data read from the data devices;
means for raising a read flag from the memory portion to indicate that the read data is not ready;
means for requesting host device to issue a re-read request after a predetermined delay;
means for performing error code correction from the memory device;
means for checking for errors; and
means for transferring the read data to the host portion.

22. The device of claim 21, wherein the data devices are NVMs.

23. The device of claim 21, wherein the memory portion is NVDIMM-P.

24. The device of claim 21, wherein the means for raising the read flag is a media controller.

25. A device, comprising:
a host portion; and
a memory portion coupled to the host portion, the memory portion including:
means for sending a write request from a host portion to a memory portion of the device;
means for checking for errors in the memory portion, wherein the means for checking for errors is configured within the memory portion of the device;
means for detecting systematic write issues with the memory portion;
means for raising a write flag from the memory portion to indicate that the write cannot be performed;
means for re-checking for errors; and
means for transferring the write data to the memory portion.

26. The device of claim 25, wherein the memory portion includes NVMs.

27. The device of claim 26, wherein the means for raising the write flag is the NVMs.

28. The device of claim 25, wherein the memory portion is NVDIMM-P.

29. The device of claim 25, wherein the means for raising the write flag is a media controller.
